(19) United States
(12) Patent Application Publication
(10) Pub. No.: US 2020/0280269 A1
(43) Pub. Date: Sep. 3, 2020

(54) VIBRATION-POWERED GENERATION DEVICE AND SENSOR SYSTEM

(71) Applicant: Panasonic Intellectual Property Management Co., Ltd., Osaka (JP)

(72) Inventors: HIDEYUKI ARAI, Osaka (JP); JUN'ICHI NAKA, Osaka (JP); TOSHIAKI OZEKI, Osaka (JP); KOJI OBATA, Osaka (JP)

(21) Appl. No.: 16/645,563

(22) PCT Filed: Oct. 26, 2018
(86) PCT No.: PCT/JP2018/039805

§ 371 Date: Mar. 9, 2020

(30) Foreign Application Priority Data
Nov. 15, 2017 (JP) 2017-220383

(51) Int. Cl. H02N 2/18; G01H 11/08; H01L 41/04; H01L 41/08; H01L 41/113; H01L 41/193; F16H 19/00; F16H 19/06; F16H 19/04

(52) U.S. Cl. CPC H02N 2/186; G01H 11/08; H01L 41/04; H01L 41/0825; F16H 19/04; H01L 41/193; F16H 19/006; F16H 19/06; H01L 41/1132

(57) ABSTRACT

The present disclosure provides a vibration power generation device capable of generating large electric power relative to an amount of displacement of a portion of a specimen. Vibration power generation device according to the present invention includes piezoelectric part and displacement enhancer. In response to displacement of a portion of specimen, displacement enhancer displaces a portion of piezoelectric part by a displacement amount greater than an amount of the displacement of the portion of specimen. When the portion of piezoelectric part is displaced, piezoelectric part generates electric power in accordance with an amount of the displacement of the portion of piezoelectric part.

### TECHNICAL FIELD

The present disclosure relates to a vibration power generation device and a sensor system. In particular, the present disclosure relates to a vibration power generation device suitable for generating electric power in response to displacement of a portion of a specimen and to a sensor system.

### BACKGROUND ART

Conventionally, vibrations (vibrational energy) from machines and other equipment have been converted into electric power.

For instance, PTL 1 discloses a vibrational energy harvester that includes a piezoelectric transducer having a layer of a piezoelectric material. An end of the piezoelectric transducer is a free end, and the vibrational energy harvester allows the free end to vibrate in response to external vibrations. The vibrational energy harvester converts vibrational energy acquired at the free end into electric energy through the layer of the piezoelectric material.

Unfortunately, in a power generation mechanism as disclosed in PTL 1, the piezoelectric transducer directly receives external vibrations and elastically vibrates. Thus, an amount of displacement of the piezoelectric transducer is likely to be small. As a result, electric power acquired by the power generation mechanism tends to be small.

### CITATION LIST

### Patent Literature

PTL 1: WO 2014/116794

### SUMMARY OF THE INVENTION

The present disclosure has been made in view of the problem described above. It is an object of the present invention to provide a vibration power generation device capable of generating large electric power relative to an amount of displacement of a portion of a specimen, as well as a sensor system including the vibration power generation device.

A vibration power generation device according to an aspect of the present disclosure includes a piezoelectric part and a displacement enhancer. In response to displacement of a portion of a specimen, the displacement enhancer displaces a portion of the piezoelectric part by a displacement amount greater than an amount of the displacement of the portion of the specimen. When the portion of the piezoelectric part is displaced, the piezoelectric part generates electric power in accordance with an amount of the displacement of the portion of the piezoelectric part.

A sensor system according to an aspect of the present disclosure includes the vibration power generation device and a sensor. The sensor includes the piezoelectric part or is a device that is different from the piezoelectric part and that is driven by electric power generated by the piezoelectric part.

The vibration power generation device according to the aspect of the present disclosure is able to generate large electric power relative to an amount of displacement of the portion of the specimen.

### BRIEF DESCRIPTION OF DRAWINGS

FIG. 1A is a schematic side view illustrating a vibration power generation device according to a first exemplary embodiment.

FIG. 1B is a schematic cross-sectional view illustrating a piezoelectric part in the vibration power generation device of the first exemplary embodiment.

FIG. 2A is a schematic side view illustrating a vibration power generation device according to a second exemplary embodiment.

FIG. 2B is a schematic side view illustrating an example mode in which the vibration power generation device of the second exemplary embodiment is attached to a suspension bridge.

FIG. 2C is a schematic side view illustrating an example mode in which the vibration power generation device of the second exemplary embodiment is attached to a cable-stayed bridge.

FIG. 3A is a schematic side view illustrating an example of a vibration power generation device according to a third exemplary embodiment.

FIG. 3B is a schematic side view illustrating another example of the vibration power generation device according to the third exemplary embodiment.

FIG. 4A is a schematic side view illustrating an example of a vibration power generation device according to a fourth exemplary embodiment.

FIG. 4B is a schematic side view illustrating another example of the vibration power generation device of the fourth exemplary embodiment.

FIG. 5 is a schematic side view illustrating a vibration power generation device according to a fifth exemplary embodiment.

FIG. 6A is a schematic side view illustrating an example of a vibration power generation device according to a sixth exemplary embodiment.

FIG. 6B is a schematic side view illustrating another example of the vibration power generation device of the sixth exemplary embodiment.

FIG. 7 is a schematic side view illustrating a vibration power generation device according to a seventh exemplary embodiment.

FIG. 8 is a schematic block diagram illustrating a sensor system according to an exemplary embodiment.

### DESCRIPTION OF EMBODIMENTS

Exemplary embodiments of the present disclosure will now be described.

### 1. Vibration Power Generation Device

Vibration power generation device 1 includes piezoelectric part 2 and displacement enhancer 3. In response to displacement of a portion of specimen 4 (hereinafter also referred to as displacement part 41), displacement enhancer 3 displaces a portion of piezoelectric part 2 (hereinafter also referred to as displacement-affected part 25) by a displacement amount greater than an amount of the displacement of displacement part 41. If displacement-affected part 25 is displaced, piezoelectric part 2 generates electric power in accordance with an amount of the displacement of displacement-affected part 25. Thus, vibration power generation device 1 is able to generate large electric power relative to the displacement amount of displacement part 41.

Exemplary embodiments of vibration power generation device 1 will be described in more detail below.

### 1.1. First Exemplary Embodiment

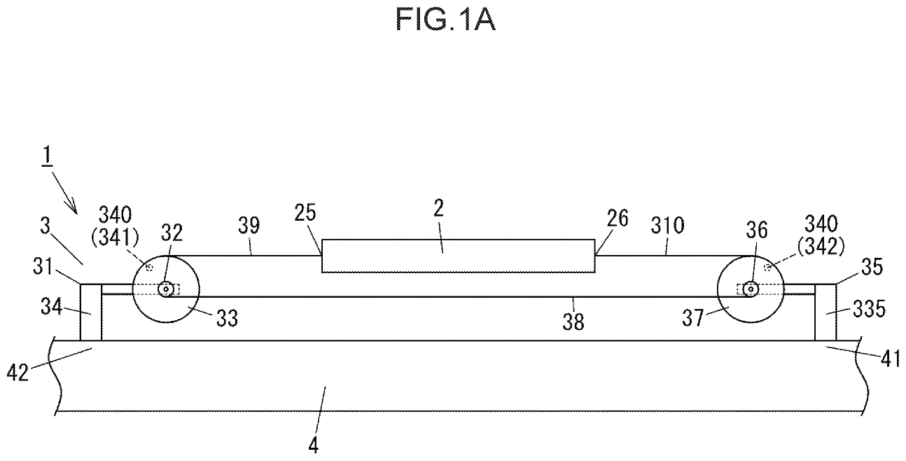

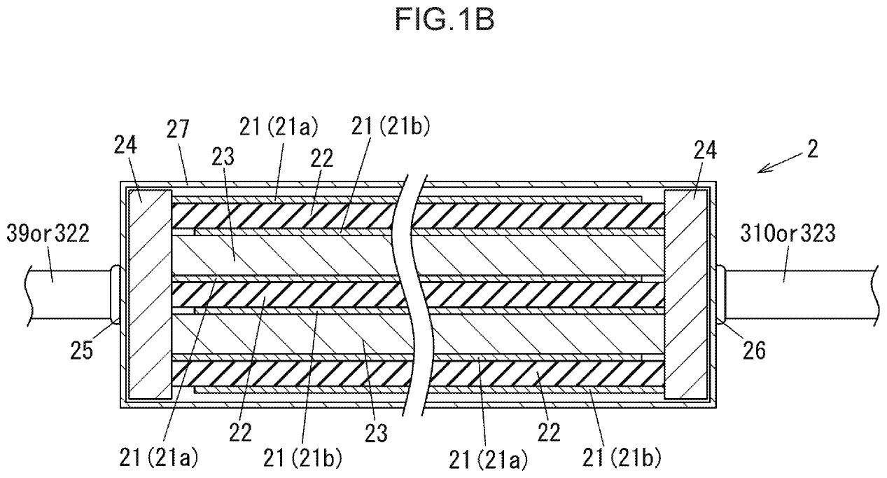

FIG. 1A schematically illustrates vibration power generation device 1 according to a first exemplary embodiment. FIG. 1B schematically illustrates piezoelectric part 2 in vibration power generation device 1.

In the first exemplary embodiment, specimen 4 is a component having a length. Specimen 4 expands and contracts in a direction of its length. Specimen 4 is, for example, a structural member of a bridge.

Vibration power generation device 1, as described above, includes piezoelectric part 2 and displacement enhancer 3.

Displacement enhancer 3 includes first pulley 32, second pulley 33 having a diameter larger than a diameter of first pulley 32, first string 38, and second string 39. First and second pulleys 32 and 33 are allowed to coaxially rotate in conjunction with each other. First string 38 is partly wound on first pulley 32 and is used to connect first pulley 32 and displacement part 41 of specimen 4 together. Second string 39 is partly wound on second pulley 33 and is used to connect second pulley 33 and displacement-affected part 25 of piezoelectric part 2 together.

More specifically, displacement enhancer 3, as shown in FIG. 1A, includes pulley unit 31 including first and second pulleys 32 and 33 and fixing unit 35. Pulley unit 31 is fixed to reference part 42, whereas fixing unit 35 is fixed to displacement part 41. In the first exemplary embodiment, a portion of specimen 4 on which pulley unit 31 is fixed is reference part 42, and a portion of specimen 4 on which fixing unit 35 is fixed is displacement part 41. Reference part 42 and displacement part 41 are spaced along the length direction of specimen 4.

Pulley unit 31 includes support 34 fixed to reference part 42 of specimen 4 and first and second pulleys 32 and 33 supported by support 34. As described above, the diameter of second pulley 33 is larger than the diameter of first pulley 32. First pulley 32 is supported by support 34 such that the first pulley is rotatable. Second pulley 33 is also supported by support 34 such that the second pulley is rotatable. First and second pulleys 32 and 33 rotate on a common rotation axis at an identical rotational speed. In other words, first and second pulleys 32 and 33 are allowed to coaxially rotate in conjunction with each other. First and second pulleys 32 and 33 are, for example, integrated together. The rotation axis is orthogonal to the length direction of specimen 4. Support 34 and first and second pulleys 32 and 33 are each made of metal, plastic, or another appropriate material.

Fixing unit 35 includes support 335 fixed to displacement part 41 of specimen 4 and third pulley 36 and fourth pulley 37 supported by support 335. A diameter of third pulley 36 is smaller than a diameter of fourth pulley 37. Third pulley 36 is supported by support 335 such that the third pulley is rotatable. Fourth pulley 37 is also supported by support 335 such that the fourth pulley is rotatable. Third and fourth pulleys 36 and 37 rotate on a common rotation axis at an identical rotational speed. In other words, third and fourth pulleys 36 and 37 are allowed to coaxially rotate in conjunction with each other. Third and fourth pulleys 36 and 37 are, for example, integrated together. The rotation axis of third and fourth pulleys 36 and 37 is parallel to the rotation axis of first and second pulleys 32 and 33. Further, first and second pulleys 32 and 33 and third and fourth pulleys 36 and 37 are aligned along the length direction of specimen 4. Support 335 and third and fourth pulleys 36 and 37 are each made of metal, plastic, or another appropriate material.

Vibration power generation device 1 also includes first string 38, second string 39, and third string 310. First string 38, second string 39, and third string 310 are each a wire, a cord, a rope, or a cable, for example. A first end of first string 38 is wound on first pulley 32 of pulley unit 31, and a second end of first string 38 is wound on third pulley 36 of fixing unit 35. As a result, first pulley 32 and displacement part 41 are connected together by first string 38 partly wound on first pulley 32 through fixing unit 35. A direction in which first string 38 is wound on first pulley 32 is opposite a direction in which first string 38 is wound on third pulley 36. A first end of second string 39 is wound on second pulley 33 of pulley unit 31, and a second end of second string 39 is connected, as described later, to displacement-affected part 25 of piezoelectric part 2. A direction in which second string 39 is wound on second pulley 33 is opposite the direction in which first string 38 is wound on first pulley 32. A first end of third string 310 is wound on fourth pulley 37 of fixing unit 35, and a second end of third string 310 is connected, as described later, to holding part 26 of piezoelectric part 2. A direction in which third string 310 is wound on fourth pulley 37 is opposite the direction in which second string 39 is wound on third pulley 36.

Piezoelectric part 2 includes at least two electrodes 21 (first electrode 21a and second electrode 21b) and piezoelectric film 22 interposed between the two electrodes 21. In the first exemplary embodiment, piezoelectric part 2, as shown in FIG. 1B, includes a plurality of piezoelectric films 22, a plurality of first electrodes 21a, a plurality of second electrodes 21b, and a plurality of insulating layers 23. These elements are stacked repeatedly in an order of first electrode 21a, piezoelectric film 22, second electrode 21b, and insulating layer 23.

Piezoelectric film 22, for example, contains a piezoelectric polymer and has an orientation. The piezoelectric polymer is, for example, poly-L-lactic acid, poly-D-lactic acid, or polyvinylidene fluoride. The orientation of piezoelectric film 22 is generated when piezoelectric film 22 is drawn at a time of manufacture. In other words, an orientation of the piezoelectric polymer contained in piezoelectric film 22 agrees with a direction in which piezoelectric film 22 is drawn. When piezoelectric film 22 is deformed by being drawn in a direction orthogonal to a direction of its thickness, piezoelectric film 22 is polarized in the direction of its thickness to generate a voltage.

Piezoelectric part 2 further includes two external electrodes 24 having conductivity. One of two external electrodes 24 is electrically connected to all first electrodes 21a and is not electrically connected to any second electrodes 21b. The other of two external electrodes 24 is electrically connected to all second electrodes 21b and is not electrically connected to any first electrodes 21a. Since piezoelectric part 2 includes external electrodes 24, eclectic power can be drawn from piezoelectric part 2 through external electrodes 24 in response to the generation of a voltage in piezoelectric films 22.

Piezoelectric part 2 further includes outer sheath 27. Outer sheath 27 houses external electrodes 24, piezoelectric films 22, first electrodes 21a, and second electrodes 21b inside. Outer sheath 27 may be made of an appropriate material.

Piezoelectric part 2 may have any structure other than the structure described above. In other words, piezoelectric part 2 may have a publicly known structure.

In the present exemplary embodiment, an end of piezoelectric part 2 facing one direction orthogonal to a direction in which electrodes 21 and piezoelectric films 22 are stacked is displacement-affected part 25. As described above, the end of second string 39 is connected to displacement-affected part 25. An end of piezoelectric part 2 opposite displacement-affected part 25 is holding part 26. As described above, the end of third string 310 is connected to holding part 26.

Operation of vibration power generation device 1 will now be described. When specimen 4 extends in the length direction, displacement part 41 is displaced, with respect to reference part 42, in a direction so as to be away from reference part 42. Since first pulley 32 and displacement part 41 are connected together by first string 38 through fixing unit 35, first pulley 32 rotates along with displacement of displacement part 41. Thus, second pulley 33 rotates in conjunction with first pulley 32. In the present exemplary embodiment, first string 38 is connected to third pulley 36 of fixing unit 35, and hence third pulley 36 of fixing unit 35 also rotates along with the displacement of displacement part 41. Thus, fourth pulley 37 rotates in conjunction with third pulley 36. In this way, second and fourth pulleys 33 and 37 rotate, and tensile force is thereby applied to piezoelectric part 2 through second and third strings 39 and 310. As a result, in piezoelectric part 2, displacement-affected part 25 is displaced, with respect to holding part 26, in a direction so as to be away from holding part 26, and piezoelectric part 2 is deformed. The deformation of piezoelectric part 2 causes piezoelectric films 22 inside piezoelectric part 2 to be deformed, resulting in the generation of a voltage by piezoelectric films 22. Thus, piezoelectric part 2 generates electric power in accordance with an amount of the displacement of displacement-affected part 25. Hence, every time specimen 4 expands and contracts, piezoelectric part 2 can generate electric power. As described above, the diameter of second pulley 33 is larger than the diameter of first pulley 32, and the diameter of fourth pulley 37 is larger than the diameter of third pulley 36. Accordingly, when displacement-affected part 25 is displaced along with the displacement of displacement part 41, the displacement amount of displacement-affected part 25 is greater than the displacement amount of displacement part 41. Thus, in response to the displacement of displacement part 41 of specimen 4, displacement enhancer 3 displaces displacement-affected part 25 of piezoelectric part 2 by a displacement amount greater than the displacement amount of displacement part 41. This configuration enables vibration power generation device 1 to generate large electric power relative to the displacement amount of displacement part 41.

Vibration power generation device 1 may have stopper 340 to place an upper limit on the displacement amount of displacement-affected part 25. In the first exemplary embodiment, vibration power generation device 1 includes first stopper 341 and second stopper 342 as stopper 340. First stopper 341 regulates rotation of first and second pulleys 32 and 33, and second stopper 342 regulates rotation of third and fourth pulleys 36 and 37. First stopper 341 is disposed on second pulley 33, and second stopper 342 is disposed on fourth pulley 37. When the displacement amount of displacement-affected part 25 reaches the upper limit, first stopper 341 gets caught by support 34 and thereby restricts the rotation of first and second pulleys 32 and 33 and second stopper 342 gets caught by support 335 and thereby restricts the rotation of third and fourth pulleys 36 and 37. In this way, first and second stoppers 341 and 342 are configured. This configuration prevents displacement-affected part 25 from being displaced to an extent that exceeds the upper limit of the displacement amount and stops piezoelectric part 2 from being damaged due to an excessive deformation. Preferably, the upper limit of the displacement amount of displacement-affected part 25 is set such that a deformation of piezoelectric part 2 does not cause piezoelectric films 22 to be deformed in excess of an elastic limit. If the piezoelectric polymer contained in piezoelectric film 22 is poly-D-lactic acid or poly-L-lactic acid, the elastic limit of piezoelectric films 22 is around 2%. If the piezoelectric polymer contained in piezoelectric film 22 is polyvinylidene fluoride, the elastic limit of piezoelectric films 22 is around 1%.

In the first exemplary embodiment, examples of specimen 4 that is a structural member of a bridge include main cables, suspender ropes, crossbeams, towers, and anchorages for suspension bridges and towers, crossbeams, and cables for cable-stayed bridges. Specimen 4 may be a combination of a plurality of kinds of structural members.

The structural member of the bridge expands and contracts slightly. If displacement part 41 is a portion of a structural member of a bridge, the displacement amount of displacement part 41 is, for example, a maximum of around 0.1 mm. Normally, it is difficult to obtain satisfactory electric power from a displacement amount of around 0.1 mm. However, in the present exemplary embodiment, in response to the displacement of displacement part 41 of specimen 4, displacement enhancer 3, as described above, displaces displacement-affected part 25 of piezoelectric part 2 by a displacement amount greater than the displacement amount of displacement part 41. For instance, the displacement amount of displacement-affected part 25 can be made as much as around 100 times the displacement amount of displacement part 41. Consequently, vibration power generation device 1 is able to obtain satisfactory electric power from the displacement of the portion of the structural member of the bridge.

The example of specimen 4 is not limited to structural members of bridges. Specimen 4 may be, for example, a structural member of a prime motor or a building, or a road as described later.

Displacement part 41 is not particularly limited, with proviso that the displacement part is a portion that is displaced with respect to reference part 42, a portion of reference. It is particularly preferred that displacement part 41 be repeatedly displaced both in a direction so as to move away from reference part 42 and in a direction so as to move nearer to reference part 42. In this case vibration power generation device 1 can generate electric power constantly.

In the first exemplary embodiment, both displacement part 41 and reference part 42 are portions of specimen 4. However, displacement part 41 and reference part 42 may be present in respective different members. With proviso that displacement part 41 is displaced with respect to reference part 42, reference part 42 may move without movement of displacement part 41 with respect to a ground, displacement part 41 may move without movement of reference part 42 with respect to a ground, or both reference part 42 and displacement part 41 may move with respect to a ground.

In the first exemplary embodiment, fixing unit 35 includes third and fourth pulleys 36 and 37. However, fixing unit 35 may not include third and fourth pulleys 36 and 37. In this case, first and third strings 38 and 310 may be fixed to fixing unit 35 without pulleys. Displacement enhancer 3 may not include fixing unit 35, and first and third strings 38 and 310 may be directly fixed to displacement part 41. In any of these cases, in response to the displacement of displacement part 41 of specimen 4, displacement enhancer 3 is able to displace displacement-affected part 25 of piezoelectric part 2 by a displacement amount greater than the displacement amount of displacement part 41, with proviso that displacement enhancer 3 includes first and second pulleys 32 and 33.

### 1.2. Second Exemplary Embodiment

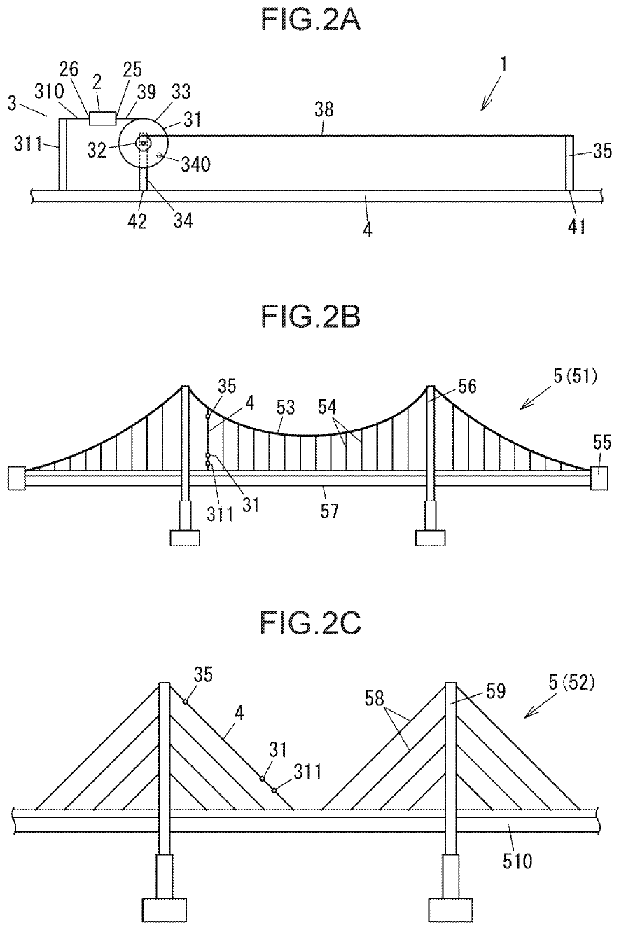

FIG. 2A schematically illustrates vibration power generation device 1 according to a second exemplary embodiment. Components in FIG. 2A that overlap those in the first exemplary embodiment are hereinafter denoted by the same numerals or symbols, and detailed descriptions thereof are omitted as appropriate.

In the second exemplary embodiment, specimen 4 is a component having a length. Specimen 4 expands and contracts in a direction of its length. Specimen 4 is, for example, a structural member of bridge 5.

Vibration power generation device 1, as described above, includes piezoelectric part 2 and displacement enhancer 3.

Displacement enhancer 3 includes first pulley 32, second pulley 33 having a diameter larger than a diameter of first pulley 32, first string 38, and second string 39. First and second pulleys 32 and 33 are allowed to coaxially rotate in conjunction with each other. First string 38 is partly wound on first pulley 32 and is used to connect first pulley 32 and displacement part 41 of specimen 4 together. Second string 39 is partly wound on second pulley 33 and is used to connect second pulley 33 and displacement-affected part 25 of piezoelectric part 2 together.

More specifically, displacement enhancer 3, as shown in FIG. 2A, includes pulley unit 31 including first and second pulleys 32 and 33 and fixing unit 35. Pulley unit 31 is fixed to reference part 42, whereas fixing unit 35 is fixed to displacement part 41. In the second exemplary embodiment, a portion of specimen 4 on which fixing unit 35 is fixed is displacement part 41, and a portion of specimen 4 on which pulley unit 31 is fixed is reference part 42. Reference part 42 and displacement part 41 are spaced along the length direction of specimen 4.

Pulley unit 31 includes support 34 fixed to reference part 42 of specimen 4 and first and second pulleys 32 and 33 supported by support 34. A configuration of pulley unit 31 in the second exemplary embodiment may be the same as that of pulley unit 31 in the first exemplary embodiment.

Fixing unit 35 is fixed to displacement part 41 of specimen 4. Fixing unit 35 is made of metal, plastic, or another appropriate material.

Vibration power generation device 1 also includes first string 38, second string 39, and third string 310. First string 38, second string 39, and third string 310 are each a wire, a cord, a rope, or a cable, for example. A first end of first string 38 is wound on first pulley 32 of pulley unit 31, and a second end of first string 38 is fixed to fixing unit 35. As a result, first pulley 32 and displacement part 41 are connected together by first string 38 partly wound on first pulley 32 through fixing unit 35. A first end of second string 39 is wound on second pulley 33 of pulley unit 31, and a second end of second string 39 is connected, as described later, to displacement-affected part 25 of piezoelectric part 2. A direction in which second string 39 is wound on second pulley 33 is opposite a direction in which first string 38 is wound on first pulley 32. Third string 310 will be described later.

Piezoelectric part 2 includes at least two electrodes 21 and piezoelectric film 22 interposed between the two electrodes 21. Piezoelectric part 2 has displacement-affected part 25 and holding part 26. A configuration of piezoelectric part 2 in the second exemplary embodiment is the same as that of piezoelectric part 2 in the first exemplary embodiment. As described above, the end of second string 39 is connected to displacement-affected part 25. An end of third string 310 is connected to holding part 26.

Vibration power generation device 1 also includes holder 311 to hold piezoelectric part 2. Holder 311 is fixed to specimen 4. Holder 311 is positioned on an opposite side of pulley unit 31 from fixing unit 35. In other words, holder 311, pulley unit 31, and fixing unit 35 are aligned in this order. A first end of third string 310 is fixed to holder 311, and a second end of third string 310 is connected, as described above, to holding part 26 of piezoelectric part 2.

Operation of vibration power generation device 1 will now be described. When specimen 4 extends in the length direction, displacement part 41 is displaced, with respect to reference part 42, in a direction so as to be away from reference part 42. Since first pulley 32 and displacement part 41 are connected together by first string 38 through fixing unit 35, first pulley 32 rotates along with displacement of displacement part 41. Thus, second pulley 33 rotates in conjunction with first pulley 32. In this way, second pulley 33 rotates, and tensile force is thereby applied to piezoelectric part 2 through second and third strings 39 and 310. As a result, in piezoelectric part 2, displacement-affected part 25 is displaced, with respect to holding part 26, in a direction so as to be away from holding part 26, and piezoelectric part 2 is deformed. The deformation of piezoelectric part 2 causes piezoelectric films 22 inside piezoelectric part 2 to be deformed, resulting in the generation of a voltage by piezoelectric films 22. Thus, piezoelectric part 2 generates electric power in accordance with an amount of the displacement of displacement-affected part 25. Hence, every time specimen 4 expands and contracts, piezoelectric part 2 can generate electric power. As described above, the diameter of second pulley 33 is larger than the diameter of first pulley 32. Accordingly, when displacement-affected part 25 is displaced along with the displacement of displacement part 41, the displacement amount of displacement-affected part 25 is greater than the displacement amount of displacement part 41. Thus, in response to the displacement of displacement part 41 of specimen 4, displacement enhancer 3 displaces displacement-affected part 25 of piezoelectric part 2 by a displacement amount greater than the displacement amount of displacement part 41. This configuration enables vibration power generation device 1 to generate large electric power relative to the displacement amount of displacement part 41.

This vibration power generation device 1 may have, in a similar way to the first exemplary embodiment, stopper 340 to place an upper limit on the displacement amount of displacement-affected part 25. In the second exemplary embodiment, stopper 340 is disposed on second pulley 33. When the displacement amount of displacement-affected part 25 reaches the upper limit, stopper 340 gets caught by support 34 and thereby restricts the rotation of first and second pulleys 32 and 33. In this way, stopper 340 is configured. This configuration prevents displacement-affected part 25 from being displaced to an extent that exceeds the upper limit of the displacement amount and stops piezoelectric part 2 from being damaged due to an excessive deformation.

In the second exemplary embodiment, examples of specimen 4 that is a structural member of bridge 5 include main cable 53, suspender rope 54, crossbeam 57, tower 56, and anchorage 55 for suspension bridge 51 and tower 59, crossbeam 510, and cable 58 for cable-stayed bridge 52. Specimen 4 may be a combination of a plurality of kinds of structural members. The example of specimen 4 is not limited to structural members of bridge 5. Specimen 4 may be, for example, a prime motor or a road as described later.

FIG. 2B illustrates an example of places at which holder 311, pulley unit 31, and fixing unit 35 are fixed when specimen 4 is a structural member of suspension bridge 51. In FIG. 2B, specimen 4 is suspender rope 54, and holder 311, pulley unit 31, and fixing unit 35 are fixed to suspender rope 54. One of pulley unit 31 and fixing unit 35 may be fixed to suspender rope 54, whereas the other of the two units may be fixed to main cable 53. One of pulley unit 31 and fixing unit 35 may be fixed to suspender rope 54, whereas the other of the two units may be fixed to crossbeam 57. Apart from these places, pulley unit 31 and fixing unit 35 may be fixed to various places on suspension bridge 51. In the first exemplary embodiment as well, pulley unit 31 and fixing unit 35 may be fixed to various places on suspension bridge 51.

FIG. 2C illustrates an example of places at which holder 311, pulley unit 31, and fixing unit 35 are fixed when specimen 4 is a structural member of a cable-stayed bridge. In FIG. 2C, specimen 4 is cable 58, and holder 311, pulley unit 31, and fixing unit 35 are fixed to cable 58. One of pulley unit 31 and fixing unit 35 may be fixed to cable 58, whereas the other of the two units may be fixed to tower 59. One of pulley unit 31 and fixing unit 35 may be fixed to cable 58, whereas the other of the two units may be fixed to crossbeam 510. Apart from these places, pulley unit 31 and fixing unit 35 may be fixed to various places on cable-stayed bridge 52. In the first exemplary embodiment as well, pulley unit 31 and fixing unit 35 may be fixed to various places on cable-stayed bridge 52.

In a similar way to the first exemplary embodiment, displacement part 41 is not particularly limited, with proviso that the displacement part is a portion that is displaced with respect to reference part 42, a portion of reference. In a similar way to the first exemplary embodiment, displacement part 41 and reference part 42 may be present in respective different members. The two parts may be configured in any way, with proviso that displacement part 41 is displaced with respect to reference part 42.

### 1.3. Third Exemplary Embodiment

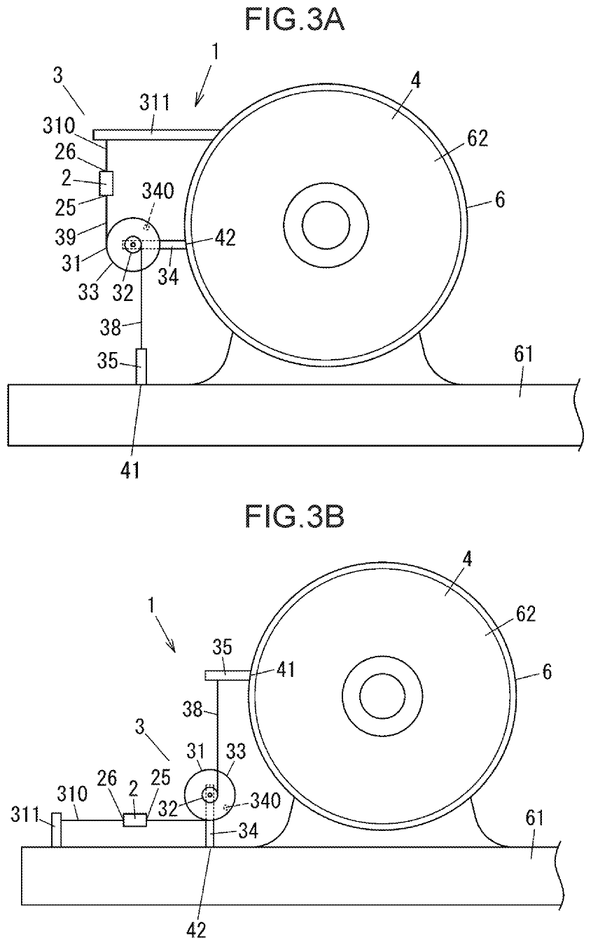

FIGS. 3A and 3B schematically illustrate vibration power generation device 1 according to a third exemplary embodiment. Components in FIGS. 3A and 3B that overlap those in the first and second exemplary embodiments are hereinafter denoted by the same numerals or symbols, and detailed descriptions thereof are omitted as appropriate.

Specimen 4 is prime motor 6. Prime motor 6 includes foundation 61 and main body 62 put on foundation 61. Main body 62 is, for example, an electric motor, an internal-combustion engine, or fluid machinery. This vibration power generation device 1 has a configuration similar to that in the second exemplary embodiment except that holder 311, pulley unit 31, and fixing unit 35 are fixed to places that differ from those in the second exemplary embodiment.

In FIG. 3A, pulley unit 31 is fixed to main body 62, and holder 311 is fixed to a part of main body 62 that is located above pulley unit 31. Fixing unit 35 is fixed to foundation 61. A portion of main body 62 on which pulley unit 31 is fixed is reference part 42, and a portion of foundation 61 on which fixing unit 35 is fixed is displacement part 41.

In the vibration power generation device shown in FIG. 3A, when main body 62 is driven and thereby vibrates, displacement part 41 of foundation 61 is displaced with respect of reference part 42 of main body 62. Accordingly, in a similar way to the second exemplary embodiment, piezoelectric part 2 is able to generate electric power.

In FIG. 3B, pulley unit 31 is fixed to foundation 61, and holder 311 is fixed to a part of foundation 61 that is located on an opposite side of pulley unit 31 from main body 62. Fixing unit 35 is fixed to a part of main body 62 that is located above pulley unit 31. A portion of foundation 61 on which pulley unit 31 is fixed is reference part 42, and the part of main body 62 on which fixing unit 35 is fixed is displacement part 41.

In the vibration power generation device shown in FIG. 3B, when main body 62 is driven and thereby vibrates, displacement part 41 of foundation 61 is displaced with respect of reference part 42 of foundation 61. Accordingly, in a similar way to the second exemplary embodiment, piezoelectric part 2 is able to generate electric power.

### 1.4. Fourth Exemplary Embodiment

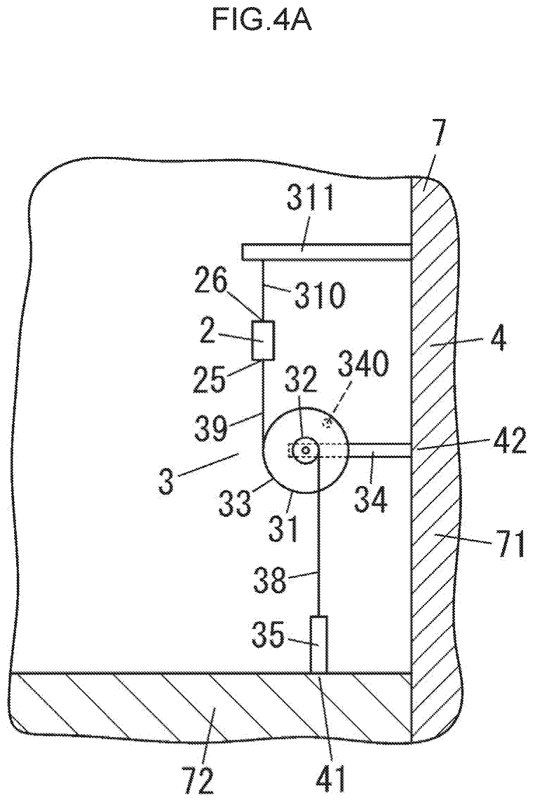

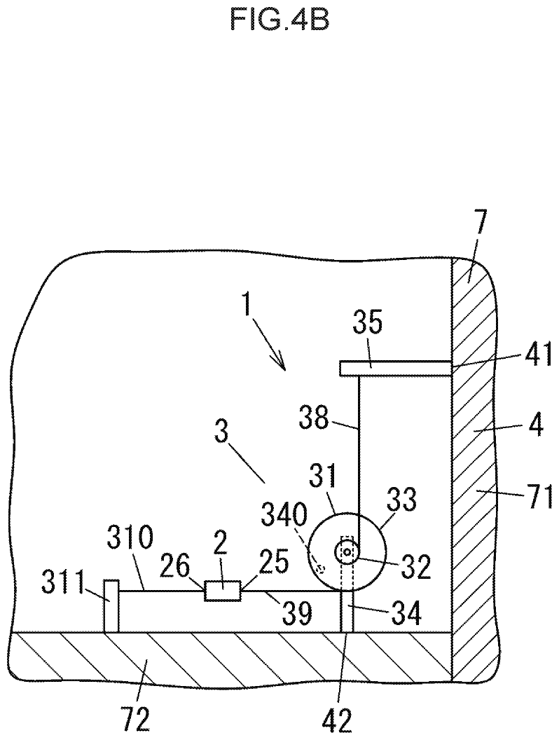

FIGS. 4A and 4B schematically illustrate vibration power generation device 1 according to a fourth exemplary embodiment. Components in FIGS. 4A and 4B that overlap those in the first to third exemplary embodiments are hereinafter denoted by the same numerals or symbols, and detailed descriptions thereof are omitted as appropriate.

Specimen 4 is a structural member of building 7. Examples of the structural member of building 7 include bases, foundations, pillar 71, beams, walls, and floor 72. This vibration power generation device 1 has a configuration similar to that in the second exemplary embodiment except that holder 311, pulley unit 31, and fixing unit 35 are fixed to places that differ from those in the second exemplary embodiment.

In FIG. 4A, pulley unit 31 is fixed to pillar 71, and holder 311 is fixed to a part of pillar 71 that is located above pulley unit 31. Fixing unit 35 is fixed to floor 72. A portion of pillar 71 on which pulley unit 31 is fixed is reference part 42, and a portion of floor 72 on which fixing unit 35 is fixed is displacement part 41.

In the vibration power generation device shown in FIG. 4A, when building 7 is shaken by an earthquake or other causes, displacement part 41 of floor 72 is displaced with respect of reference part 42 of pillar 71. Accordingly, in a similar way to the second exemplary embodiment, piezoelectric part 2 is able to generate electric power.

In FIG. 4B, pulley unit 31 is fixed to floor 72, and holder 311 is fixed to a part of floor 72 that is located on an opposite side of pulley unit 31 from pillar 71. Fixing unit 35 is fixed to a part of pillar 71 that is located above pulley unit 31. A portion of floor 72 on which pulley unit 31 is fixed is reference part 42, and the part of pillar 71 on which fixing unit 35 is fixed is displacement part 41.

In the vibration power generation device shown in FIG. 4B, when building 7 is shaken by an earthquake or other causes, displacement part 41 of pillar 71 is displaced with respect of reference part 42 of floor 72. Accordingly, in a similar way to the second exemplary embodiment, piezoelectric part 2 is able to generate electric power.

### 1.5. Fifth Exemplary Embodiment

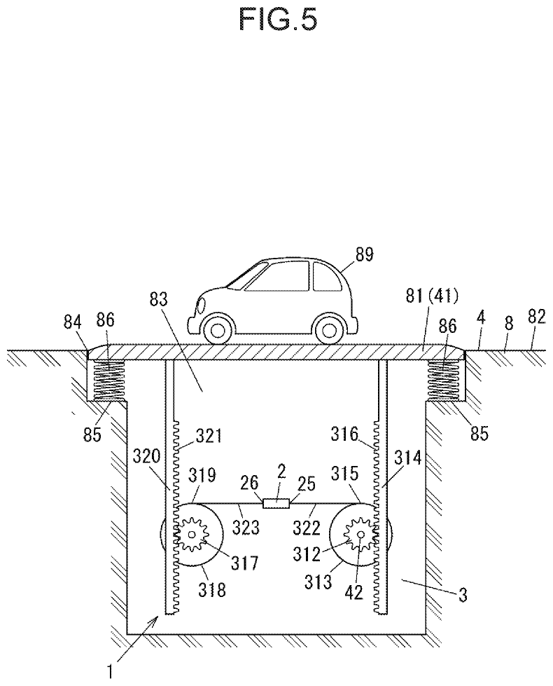

FIG. 5 schematically illustrates vibration power generation device 1 according to a fifth exemplary embodiment. Components in FIG. 5 that overlap those in the first to fourth exemplary embodiments are hereinafter denoted by the same numerals or symbols, and detailed descriptions thereof are omitted as appropriate.

In the present exemplary embodiment, displacement enhancer 3 includes toothed wheel 312 and rack 314. Rack 314 is fixed to displacement part 41 of specimen 4 and engages with toothed wheel 312.

In the present exemplary embodiment, displacement enhancer 3 further includes circular component 313. Circular component 313 has a diameter larger than a diameter of toothed wheel 312. Toothed wheel 312 and circular component 313 are allowed to coaxially rotate in conjunction with each other. A portion of piezoelectric part 2 is connected to an outer circumference of circular component 313.

A configuration of vibration power generation device 1 will be described more specifically.

In the present exemplary embodiment, specimen 4 is road 8. Plate 81 that constitutes a portion of road 8 is displacement part 41.

In the present exemplary embodiment, storage space 83 exists below ground 82. Storage space 83 has opening 84 through which to communicate with an atmosphere above the ground. Plate 81 is disposed so as to close opening 84. Displacement enhancer 3 and piezoelectric part 2 are housed in storage space 83.

Disposition area 85 is formed near an edge of opening 84 inside storage space 83. Disposition area 85 is a surface facing upward and being located at a level higher than a bottom surface of storage space 83. Coil spring 86 is disposed on disposition area 85. Plate 81 is supported by coil spring 86. Hence, if a load is downwardly applied to plate 81, coil spring 86 is elastically deformed and plate 81 is thereby displaced downward, and subsequently, when the load disappears, coil spring 86 returns to its original shape and plate 81 is thereby put back into position. In this way, plate 81 is configured.

Displacement enhancer 3 has first gear unit 315 including toothed wheel 312 and circular component 313 and second gear unit 319 including second toothed wheel 317 and second circular component 318. Circular component 313 and second circular component 318 are circular members. In the present exemplary embodiment, both circular component 313 and second circular component 318 are pulleys. First and second gear units 315 and 319 are disposed so as to be spaced along a direction parallel to a horizontal plane.

In first gear unit 315, a diameter of circular component 313 is larger than a diameter of toothed wheel 312. Circular component 313 and toothed wheel 312 rotate on a common rotation axis at an identical rotational speed. In other words, circular component 313 and toothed wheel 312 are allowed to coaxially rotate in conjunction with each other. Circular component 313 and toothed wheel 312 are, for example, integrated together. The rotation axis is parallel to the horizontal plane and is orthogonal to a direction along which first and second gear units 315 and 319 are aligned. Circular component 313 and toothed wheel 312 are each made of metal, plastic, or another appropriate material.

In second gear unit 319, a diameter of second circular component 318 is larger than a diameter of second toothed wheel 317. Second circular component 318 and second toothed wheel 317 rotate on a common rotation axis at an identical rotational speed. In other words, second circular component 318 and second toothed wheel 317 are allowed to coaxially rotate in conjunction with each other. Second circular component 318 and second toothed wheel 317 are, for example, integrated together. The rotation axis is parallel to the horizontal plane and is orthogonal to a direction along which first and second gear units 315 and 319 are aligned. Second circular component 318 and second toothed wheel 317 are each made of metal, plastic, or another appropriate material.

Displacement enhancer 3 also includes rack 314 and second rack 320. Rack 314 has a length. A direction of the length of rack 314 runs parallel with a vertical direction. Rack 314 has gear face 316 that faces in a direction orthogonal to the length direction of rack 314. Gear face 316 has gear teeth. Second rack 320 also has a length. A direction of the length of second rack 320 runs parallel with the vertical direction. Second rack 320 has gear face 321 that faces in a direction orthogonal to the length direction of second rack 320. Gear face 321 has gear teeth. Rack 314 is disposed on an opposite side of toothed wheel 312 from second gear unit 319. Gear face 316 of rack 314 faces toothed wheel 312, and the gear teeth on gear face 316 engage with toothed wheel 312. An upper end of rack 314 is fixed to plate 81. Second rack 320 is disposed on an opposite side of second toothed wheel 317 from first gear unit 315. Gear face 321 of second rack 320 faces second toothed wheel 317, and the gear teeth on gear face 321 engage with second toothed wheel 317. An upper end of second rack 320 is also fixed to plate 81.

In the present exemplary embodiment, vibration power generation device 1 also includes first string 322 and second string 323. First string 322 and second string 323 are each a wire, a cord, a rope, or a cable, for example. A first end of first string 322 is wound on circular component 313 of first gear unit 315, and a second end of first string 322 is connected, as described later, to displacement-affected part 25 of piezoelectric part 2. As a result, the outer circumference of circular component 313 and displacement-affected part 25 of piezoelectric part 2 are connected together through first string 322. A first end of second string 323 is wound on second circular component 318 of second gear unit 319, and a second end of second string 323 is connected, as described later, to holding part 26 of piezoelectric part 2. As a result, an outer circumference of second circular component 318 and holding part 26 of piezoelectric part 2 are connected together through second string 323. A direction in which second string 323 is wound on second circular component 318 is opposite a direction in which first string 322 is wound on circular component 313.

Piezoelectric part 2 includes at least two electrodes 21 and piezoelectric film 22 interposed between the two electrodes 21. Piezoelectric part 2 has displacement-affected part 25 and holding part 26. A configuration of piezoelectric part 2 in the fifth exemplary embodiment is the same as that of piezoelectric part 2 in the first exemplary embodiment. As described above, the end of first string 322 is connected to displacement-affected part 25. The end of second string 323 is connected to holding part 26.

In the present exemplary embodiment, reference part 42 may be any portion that is not displaced in response to the displacement of displacement part 41. For instance, the reference part is at a place where toothed wheel 312 is disposed.

Operation of vibration power generation device 1 will now be described. When automobile 89 passes on plate 81, which is displacement part 41, plate 81 is displaced downward with respect to reference part 42 owing to a load downwardly applied to plate 81 by automobile 89. Along with the displacement of plate 81, rack 314 and second rack 320 move downward and in response to the movement, toothed wheel 312 engaging with rack 314 and second toothed wheel 317 engaging with second rack 320 rotate. The rotating directions of toothed wheel 312 and second toothed wheel 317 are opposite to each other. Circular component 313 rotates along with the rotation of toothed wheel 312, and second circular component 318 rotates along with the rotation of second toothed wheel 317. Hence, tensile force is applied to piezoelectric part 2 from the outer circumferences of circular component 313 and second circular component 318 through first and second strings 322 and 323. As a result, in piezoelectric part 2, displacement-affected part 25 is displaced, with respect to holding part 26, in a direction so as to be away from holding part 26, and piezoelectric part 2 is deformed. Because of the deformation of piezoelectric part 2, piezoelectric part 2 generates electric power in accordance with an amount of the displacement of displacement-affected part 25. Thus, every time automobile 89 passes on plate 81, which is a portion of specimen 4, and plate 81 thereby descends, piezoelectric part 2 can generate electric power. As described above, the diameter of circular component 313 is larger than the diameter of toothed wheel 312, and the diameter of second circular component 318 is larger than the diameter of second toothed wheel 317. Accordingly, when displacement-affected part 25 is displaced along with the displacement of displacement part 41, the displacement amount of displacement-affected part 25 is greater than the displacement amount of displacement part 41. Thus, in response to the displacement of displacement part 41 of specimen 4, displacement enhancer 3 displaces displacement-affected part 25 of piezoelectric part 2 by a displacement amount greater than the displacement amount of displacement part 41. This configuration enables vibration power generation device 1 to generate large electric power relative to the displacement amount of displacement part 41.

In the fifth exemplary embodiment, vibration power generation device 1 includes second gear unit 319 and second string 323. Vibration power generation device 1 may, however, not include second gear unit 319 and second string 323. In this case, holding part 26 of piezoelectric part 2 may be fixed inside storage space 83 by an appropriate method. Even in this case, in response to the displacement of plate 81, displacement enhancer 3 is able to displace displacement-affected part 25 of piezoelectric part 2 by a displacement amount greater than the displacement amount of plate 81, with proviso that displacement enhancer 3 includes toothed wheel 312, circular component 313, and rack 314.

In the fifth exemplary embodiment, as described above, circular component 313 is a pulley, and the outer circumference of circular component 313 and displacement-affected part 25 of piezoelectric part 2 are connected together through first string 322. However, the outer circumference of circular component 313 and displacement-affected part 25 may be connected together by another method. For instance, circular component 313 may be equivalent to toothed wheel 312, and an outer circumference of circular component 313 and displacement-affected part 25 may be connected together through a rack. In other words, displacement enhancer 3 may include another rack different from rack 314 and second rack 320 described above, and the other rack may engage with circular component 313 and be fixed to displacement part 41. In the present exemplary embodiment, as described above, second circular component 318 is a pulley, and the outer circumference of second circular component 318 and holding part 26 of piezoelectric part 2 are connected together through second string 323. However, the outer circumference of second circular component 318 and holding part 26 may be connected together by another method. For instance, second circular component 318 may be equivalent to toothed wheel 312, and an outer circumference of second circular component 318 and holding part 26 may be connected together through a rack. In other words, displacement enhancer 3 may include another rack different from rack 314 and second rack 320 described above, and the other rack may engage with second circular component 318 and be fixed to holding part 26.

The example of specimen 4 is not limited to road 8. Specimen 4 may be, for example, a structural member of a bridge, or a structural member of a prime motor or a building.

### 1.6. Sixth Exemplary Embodiment

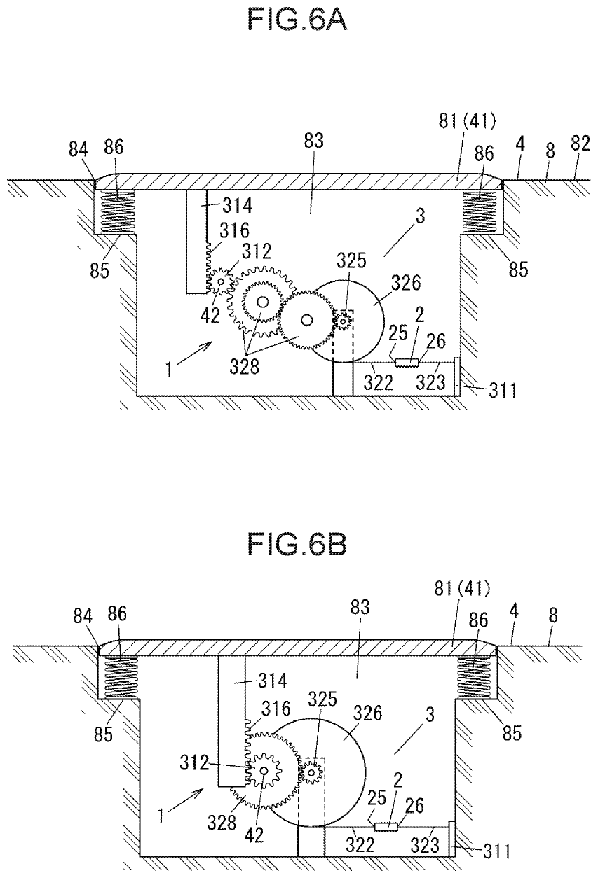

FIGS. 6A and 6B schematically illustrate vibration power generation device 1 according to a sixth exemplary embodiment. Components in FIGS. 6A and 6B that overlap those in the first to fifth exemplary embodiments are hereinafter denoted by the same numerals or symbols, and detailed descriptions thereof are omitted as appropriate.

In the present exemplary embodiment in a similar way to the fifth exemplary embodiment, displacement enhancer 3 includes toothed wheel 312 and rack 314. Rack 314 is fixed to displacement part 41 of specimen 4 and engages with toothed wheel 312.

In the present exemplary embodiment, displacement enhancer 3 further includes second toothed wheel 325 and circular component 326. Second toothed wheel 325 is configured so as to receive turning force transferred from toothed wheel 312. Circular component 326 has a diameter larger than a diameter of second toothed wheel 325. Second toothed wheel 325 and circular component 326 are allowed to coaxially rotate in conjunction with each other. Displacement-affected part 25 of piezoelectric part 2 is connected to an outer circumference of circular component 326.

A configuration of vibration power generation device 1 will be described more specifically.

In the present exemplary embodiment, specimen 4 is road 8. Plate 81 that constitutes a portion of road 8 is displacement part 41.

In the present exemplary embodiment in a similar way to the fifth exemplary embodiment, storage space 83 exists below a ground. Storage space 83 has opening 84 through which to communicate with an atmosphere above the ground. Plate 81 is disposed so as to close opening 84. Displacement enhancer 3 and piezoelectric part 2 are housed in storage space 83.

In a similar way to the fifth exemplary embodiment, disposition area 85 is formed near an edge of opening 84 inside storage space 83. Coil spring 86 is disposed on disposition area 85. Plate 81 is supported by coil spring 86.

Displacement enhancer 3 has a gear mechanism that includes toothed wheel 312, second toothed wheel 325, and circular component 326. Circular component 326 is a circular member. In the present exemplary embodiment, circular component 326 is a pulley.

The diameter of circular component 326 is larger than the diameter of second toothed wheel 325. Circular component 326 and second toothed wheel 325 rotate on a common rotation axis at an identical rotational speed. In other words, circular component 326 and second toothed wheel 325 are allowed to coaxially rotate in conjunction with each other. Circular component 326 and second toothed wheel 325 are, for example, integrated together. Toothed wheel 312, circular component 326, and second toothed wheel 325 are each made of metal, plastic, or another appropriate material. Preferably, the diameter of circular component 326 is larger than a diameter of toothed wheel 312.

The gear mechanism includes at least one intermediate toothed wheel 328 to transfer turning force between toothed wheel 312 and second toothed wheel 325. In the gear mechanism, toothed wheel 312 and intermediate toothed wheel 328 rotate while engaging with each other (see FIG. 6A), or toothed wheel 312 and intermediate toothed wheel 328 coaxially rotate (see FIG. 6B), for example, and turning force is thereby transferred from toothed wheel 312 to intermediate toothed wheel 328. In the gear mechanism, two intermediate toothed wheels 328 rotate while engaging with each other (see FIG. 6A), or two intermediate toothed wheels 328 coaxially rotate (see FIG. 6A), for example, and turning force is thereby transferred between intermediate toothed wheels 328. In the gear mechanism, intermediate toothed wheel 328 and second toothed wheel 325 rotate while engaging with each other (see FIGS. 6A and 6B), or intermediate toothed wheel 328 and second toothed wheel 325 coaxially rotate, for example, and turning force is thereby transferred from intermediate toothed wheel 328 to second toothed wheel 325. In the gear mechanism, one revolution of toothed wheel 312 preferably causes second toothed wheel 325 to rotate at a number of revolutions greater than one. Preferably, in such a way, toothed wheel 312, intermediate toothed wheel 328, and second toothed wheel 325 included in the gear mechanism are configured.

Displacement enhancer 3 also includes rack 314. Rack 314 has a length. A direction of the length of rack 314 runs parallel with a vertical direction. Rack 314 has gear face 316 that faces in a direction orthogonal to the length direction of rack 314. Gear face 316 has gear teeth. Rack 314 is disposed on an opposite side of toothed wheel 312 from second toothed wheel 325. Gear face 316 of rack 314 faces toothed wheel 312, and the gear teeth on gear face 316 engage with toothed wheel 312. An upper end of rack 314 is fixed to plate 81.

In the present exemplary embodiment, vibration power generation device 1 further includes first string 322. First string 322 is a wire, a cord, a rope, or a cable, for example. A first end of first string 322 is wound on circular component 326, and a second end of first string 322 is connected, as described later, to displacement-affected part 25 of piezoelectric part 2. As a result, the outer circumference of circular component 326 and displacement-affected part 25 of piezoelectric part 2 are connected together through first string 322.

In the present exemplary embodiment, vibration power generation device 1 further includes holder 311 and second string 323. Holder 311 is fixed to an interior of storage space 83. A first end of second string 323 is fixed to holder 311, and a second end of second string 323 is connected, as described later, to holding part 26 of piezoelectric part 2.

Piezoelectric part 2 includes at least two electrodes 21 and piezoelectric film 22 interposed between the two electrodes 21. Piezoelectric part 2 has displacement-affected part 25 and holding part 26. A configuration of piezoelectric part 2 in the fifth exemplary embodiment is the same as that of piezoelectric part 2 in the first exemplary embodiment. As described above, the end of first string 322 is connected to displacement-affected part 25. The end of second string 323 is connected, as described above, to holding part 26.

In the present exemplary embodiment, reference part 42 is at a place where toothed wheel 312 is disposed.

Operation of vibration power generation device 1 will now be described. When an automobile passes on plate 81, which is displacement part 41, plate 81 is displaced downward with respect to reference part 42 owing to a load downwardly applied to plate 81 by the automobile. Along with the displacement of plate 81, rack 314 moves downward and in response to the movement, toothed wheel 312 engaging with rack 314 rotates. In the gear mechanism, turning force is transferred from toothed wheel 312 to second toothed wheel 325. Along with the rotation of second toothed wheel 325, circular component 326 rotates. Hence, tensile force is applied to piezoelectric part 2 from the outer circumferences of circular component 326 through first string 322. As a result, in piezoelectric part 2, displacement-affected part 25 is displaced, with respect to holding part 26, in a direction so as to be away from holding part 26, and piezoelectric part 2 is deformed. Because of the deformation of piezoelectric part 2, piezoelectric part 2 generates electric power in accordance with an amount of the displacement of displacement-affected part 25. Thus, every time an automobile passes on plate 81, which is a portion of specimen 4, and plate 81 thereby descends, piezoelectric part 2 can generate electric power.

In the present exemplary embodiment, displacement enhancer 3 is able to make the displacement amount of displacement-affected part 25 larger than an amount of the displacement of displacement part 41 if the diameter of toothed wheel 312, the diameter of second toothed wheel 325, the diameter of circular component 326, and the number of revolutions of second toothed wheel 325 in response to one revolution of toothed wheel 312 are appropriately designed. Hence, in response to the displacement of displacement part 41 of specimen 4, displacement enhancer 3 is able to displace displacement-affected part 25 of piezoelectric part 2 by a displacement amount greater than the displacement amount of displacement part 41. This configuration enables vibration power generation device 1 to generate large electric power relative to the displacement amount of displacement part 41.

In the sixth exemplary embodiment, as described above, circular component 326 is a pulley, and the outer circumference of circular component 326 and displacement-affected part 25 of piezoelectric part 2 are connected together through first string 322. However, the outer circumference of circular component 326 and displacement-affected part 25 may be connected together by another method. For instance, circular component 326 may be a toothed wheel, and an outer circumference of circular component 326 and displacement-affected part 25 may be connected together through a rack. In other words, displacement enhancer 3 may include another rack different from rack 314 described above, and the other rack may engage with circular component 326 and be fixed to displacement part 41.

In the sixth exemplary embodiment, displacement enhancer 3 may not include intermediate toothed wheel 328, and toothed wheel 312 may engage with second toothed wheel 325. In this case as well, displacement enhancer 3 is able to make the displacement amount of displacement-affected part 25 larger than an amount of the displacement of displacement part 41 if the diameter of toothed wheel 312, the diameter of second toothed wheel 325, the diameter of circular component 326, and the number of revolutions of second toothed wheel 325 in response to one revolution of toothed wheel 312 are appropriately designed.

In the sixth exemplary embodiment, displacement enhancer 3 may include an element used to transfer turning force from toothed wheel 312 to second toothed wheel 325, other than intermediate toothed wheel 328. Examples of the element include timing belts, timing chains, and other endless belts.

The example of specimen 4 is not limited to road 8. Specimen 4 may be, for example, a structural member of a bridge, or a structural member of a prime motor or a building.

### 1.7. Seventh Exemplary Embodiment

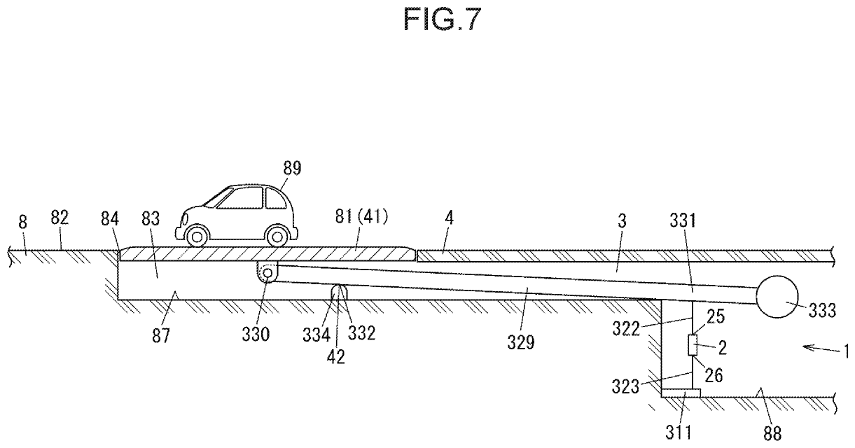

FIG. 7 schematically illustrates vibration power generation device 1 according to a seventh exemplary embodiment. Components in FIG. 7 that overlap those in the first to sixth exemplary embodiments are hereinafter denoted by the same numerals or symbols, and detailed descriptions thereof are omitted as appropriate.

In the present exemplary embodiment, displacement enhancer 3 includes lever 329. A point of effort 330 of lever 329 is connected to displacement part 41 of specimen 4 whereas a point of load 331 of lever 329 is connected to displacement-affected part 25 of piezoelectric part 2. A distance from the point of load 331 to fulcrum 332 of lever 329 is larger than a distance from the point of effort 330 to fulcrum 332.

A configuration of vibration power generation device 1 will be described more specifically.

In the present exemplary embodiment, specimen 4 is road 8. Plate 81 that constitutes a portion of road 8 is displacement part 41.

In the present exemplary embodiment, storage space 83 exists below a ground. Storage space 83 has opening 84 through which to communicate with an atmosphere above the ground. Plate 81 is disposed so as to close opening 84. Displacement enhancer 3 and piezoelectric part 2 are housed in storage space 83.

Displacement enhancer 3 includes lever 329. Lever 329 has the point of effort 330, fulcrum 332, and the point of load 331. Lever 329 is a member having a length. Lever 329 has a first end and a second end on both ends along a longitudinal axis. The point of effort 330 is located at the first end of lever 329, and the point of load 331 is located near the second end of lever 329. Fulcrum 332 is at a place between the point of effort 330 and the point of load 331 of lever 329. As described above, the distance from the point of load 331 to fulcrum 332 is larger than the distance from the point of effort 330 to fulcrum 332. Weight 333 is disposed at the second end of lever 329.

The point of effort 330 of lever 329 is attached to a lower surface of plate 81. Thus, the point of effort 330 of lever 329 is connected to plate 81. While no load is downwardly applied to plate 81, the first end of lever 329 is disposed at a level higher than the second end because of a load applied downwardly to the second end by weight 333. As a result, lever 329 supports plate 81 at a place so as to close opening 84.

A bottom of storage space 83 includes first bottom 87 and second bottom 88 disposed at a level lower than first bottom 87. The first end, the point of effort 330, and fulcrum 332 of lever 329 are located above first bottom 87, whereas the point of load 331 and the second end of lever 329 are located above second bottom 88.

Displacement enhancer 3 further includes support member 334 to support fulcrum 332 of lever 329. Support member 334 is placed on first bottom 87.

Displacement enhancer 3 further includes holder 311, first string 322, and second string 323. Holder 311 is fixed to a part of second bottom 88 directly below the point of load 331 of lever 329. A first end of first string 322 is fixed to the point of load 331 of lever 329, and a second end of first string 322 is connected, as described later, to displacement-affected part 25 of piezoelectric part 2. A first end of second string 323 is fixed to holder 311, and a second end of second string 323 is fixed, as described later, to holding part 26 of piezoelectric part 2.

Piezoelectric part 2 includes at least two electrodes 21 and piezoelectric film 22 interposed between the two electrodes 21. Piezoelectric part 2 has displacement-affected part 25 and holding part 26. A configuration of piezoelectric part 2 in the seventh exemplary embodiment is the same as that of piezoelectric part 2 in the first exemplary embodiment. As described above, the end of first string 322 is connected to displacement-affected part 25. The end of second string 323 is connected, as described above, to holding part 26.

In the present exemplary embodiment, reference part 42 may be any portion that is not displaced in response to the displacement of displacement part 41. For instance, the reference part is at a place where fulcrum 332 of lever 329 is disposed.

Operation of vibration power generation device 1 will now be described. When automobile 89 passes on plate 81, which is displacement part 41, a load is downwardly applied to the point of effort 330 of lever 329 via plate 81 owing to a load downwardly applied to plate 81 by automobile 89. As a result, plate 81 is displaced downward with respect to reference part 42. Along with the displacement, lever 329 operates such that the point of effort 330 goes down against the load of weight 333 and the point of load 331 rises. To ensure that lever 329 operates in this way, mass of weight 333 is appropriately set. Along with the rise of the point of load 331, tensile force is applied to displacement-affected part 25 of piezoelectric part 2 from the point of load 331 of lever 329 through first string 322. As a result, in piezoelectric part 2, displacement-affected part 25 is displaced, with respect to holding part 26, in a direction so as to be away from holding part 26, and piezoelectric part 2 is deformed. Because of the deformation of piezoelectric part 2, piezoelectric part 2 generates electric power in accordance with an amount of the displacement of displacement-affected part 25. Thus, every time an automobile passes on plate 81, which is a portion of specimen 4, and plate 81 thereby descends, piezoelectric part 2 can generate electric power.

In the present exemplary embodiment, the distance from the point of load 331 to fulcrum 332 of lever 329 is, as described above, larger than the distance from the point of effort 330 to fulcrum 332. Accordingly, an amount of the upward movement of the point of load 331 is larger than an amount of the downward movement of the point of effort 330 along with the displacement of plate 81. Hence, in response to the displacement of displacement part 41 of specimen 4, displacement enhancer 3 is able to displace displacement-affected part 25 of piezoelectric part 2 by a displacement amount greater than the displacement amount of displacement part 41. This configuration enables vibration power generation device 1 to generate large electric power relative to the displacement amount of displacement part 41.

The example of specimen 4 is not limited to road 8. Specimen 4 may be, for example, a structural member of a bridge, or a structural member of a prime motor or a building.

### 2. Sensor System

Sensor system 9 that includes vibration power generation device 1 will now be described.

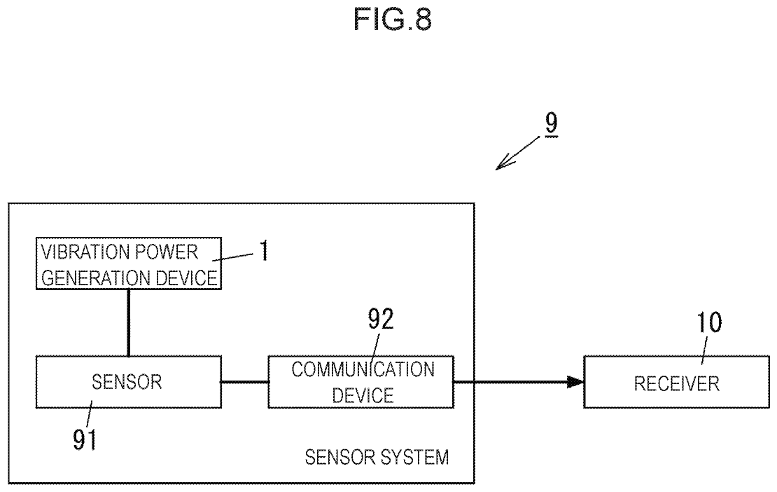

FIG. 8 is a block diagram of an example of sensor system 9. Sensor system 9 includes vibration power generation device 1 and sensor 91. Sensor 91 is made up of piezoelectric part 2 included in vibration power generation device 1 or is a device that is different from piezoelectric part 2 and that is driven by electric power generated by piezoelectric part 2. Sensor system 9 may further include, as shown in FIG. 8, communication device 92 that transmits a result detected with sensor 91.

If sensor 91 is piezoelectric part 2, sensor 91 outputs a signal in response to displacement of displacement part 41 of specimen 4. If specimen 4 is, for example, a structural member of a bridge as in the first and second exemplary embodiments, sensor 91 is able to detect a vibration created in the structural member of the bridge and output a signal in response to the vibration. In this case, sensor system 9 can be used, for example, to check whether an excessive vibration is created in the structural member of the bridge. If specimen 4 is a prime motor as in the third exemplary embodiment, sensor 91 is able to detect a vibration created in the prime motor and output a signal in response to the vibration. In this case, sensor system 9 can be used, for example, to check whether an abnormal vibration is created in the prime motor. If specimen 4 is a structural member of a building as in the fourth exemplary embodiment, sensor 91 is able to detect a vibration created in the structural member of the building and output a signal in response to the vibration. In this case, sensor system 9 can be used, for example, as a seismograph. If specimen 4 is a road as in the fifth to seventh exemplary embodiments, sensor 91 is able to detect a displacement of a portion of the road when an automobile passes on the road portion and output a signal in response to the displacement. In this case, sensor system 9 can be used, for example, to investigate automobile traffic on the road.

If sensor 91 is different from piezoelectric part 2 and is driven by electric power generated by piezoelectric part 2, information detected with sensor 91 may contain any facts. Sensor 91 may be, for example, a temperature sensor, a humidity sensor, a gas sensor, or an image sensor. In this case, sensor system 9 is able to detect information about temperature, humidity, gas composition, image, or others at a location where sensor system 9 is placed or in an area around the location.

Sensor system 9 according to the present exemplary embodiment is not required to receive the supply of electric power from an outside in order to drive sensor 91. Thus, sensor system 9 is able to detect information in accordance with a type of sensor 91 through sensor 91 even at a place where it is difficult to receive the supply of electric power.

If sensor system 9 includes communication device 92, sensor system 9 is able to transmit a result detected with sensor 91 to receiver 10 installed outside as appropriate via communication device 92. Communication device 92 may transmit the detection result by wire or wireless. Communication device 92 may be driven by electric power generated by vibration power generation device 1 or by electric power supplied from a power source different from vibration power generation device 1.

### REFERENCE MARKS IN THE DRAWINGS

1 vibration power generation device
2 piezoelectric part
21 electrode
22 piezoelectric film
25 displacement-affected part
3 displacement enhancer
32 first pulley
33 second pulley
38 first string
39 second string
312 toothed wheel
313 circular component
314 rack
322 first string
323 second string
326 circular component
329 lever
330 point of effort
331 point of load
332 fulcrum
4 specimen
41 displacement part
5 bridge
6 prime motor
7 building
8 road
9 sensor system
91 sensor
92 communication device

1. A vibration power generation device comprising:
a piezoelectric part; and
a displacement enhancer,
wherein in response to displacement of a portion of a specimen, the displacement enhancer displaces a portion of the piezoelectric part by a displacement amount greater than an amount of the displacement of the portion of the specimen, and
wherein when the portion of the piezoelectric part is displaced, the piezoelectric part generates electric power in accordance with the amount of the displacement of the portion of the piezoelectric part.

2. The vibration power generation device according to claim 1, wherein
the piezoelectric part includes at least two electrodes, and a piezoelectric film interposed between the at least two electrodes, and
wherein when the portion of the piezoelectric part is displaced, the piezoelectric film deforms to generate a voltage.

3. The vibration power generation device according to claim 1, wherein
the displacement enhancer includes a first pulley, a second pulley having a diameter larger than a diameter of the first pulley, a first string, and a second string,
wherein the first pulley and the second pulley are allowed to coaxially rotate in conjunction with each other,
wherein the first string is partly wound on the first pulley and is used to connect the first pulley and the portion of the specimen together, and
wherein the second string is partly wound on the second pulley and is used to connect the second pulley and the portion of the piezoelectric part together.

4. The vibration power generation device according to claim 1, wherein
the displacement enhancer includes a toothed wheel, and a rack, and
wherein the rack is fixed to the portion of the specimen and engages with the toothed wheel.

5. The vibration power generation device according to claim 4, wherein
the displacement enhancer further includes a circular component,
wherein the circular component has a diameter larger than a diameter of the toothed wheel, the toothed wheel and the circular component are allowed to coaxially rotate in conjunction with each other, and
wherein the portion of the piezoelectric part is connected to an outer circumference of the circular component.

6. The vibration power generation device according to claim 4, wherein
the displacement enhancer further includes a second toothed wheel, and a circular component,
wherein the second toothed wheel is configured so as to receive turning force transferred from the toothed wheel,
wherein the circular component has a diameter larger than a diameter of the second toothed wheel, and the second toothed wheel and the circular component are allowed to coaxially rotate in conjunction with each other, and
wherein the portion of the piezoelectric part is connected to an outer circumference of the circular component.

7. The vibration power generation device according to claim 1, wherein
the displacement enhancer includes a lever,
wherein a point of effort of the lever is connected to the portion of the specimen whereas a point of load of the lever is connected to the portion of the piezoelectric part, and
wherein a distance from the point of load to a fulcrum of the lever is larger than a distance from the point of effort to the fulcrum.

8. The vibration power generation device according to claim 1, wherein the specimen is any one of a structural member of a bridge, a prime motor, and a road.

9. A sensor system comprising:
the vibration power generation device according to claim 1; and
a sensor,
wherein the sensor includes the piezoelectric part or is a device that is different from the piezoelectric part and that is driven by electric power generated by the piezoelectric part.

10. The sensor system according to claim 9, further comprising a communication device that transmits a result detected with the sensor.
